(19) United States
(12) Patent Application Publication
(10) Pub. No.: US 2006/0272713 A1
(43) Pub. Date: Dec. 7, 2006

(54) Microfluidic devices with integrated tubular structures

(76) Inventors: Sean M. Garner, Elmira, NY (US); James S. Sutherland, Corning, NY (US)

Correspondence Address: CORNING INCORPORATED, SP-TI-3-1, CORNING, NY, 14831, US

(21) Appl. No.: 11/440,861

(22) Filed: May 24, 2006

Related U.S. Application Data
(60) Provisional application No. 60/686,190, filed on May 31, 2005.

(51) Int. Cl. B81B 1/00; B81C 5/00

(52) U.S. Cl. 137/561 R; 29/890.09

(57) ABSTRACT

A microfluidic device is disclosed comprising a body of refractory material having one or more fluid passages of millimeter-or sub-millimeter scale defined therein and at least one tube of refractory material embedded in said body, the tube having a millimeter- or sub-millimeter-scale passage therein and first and second ends. The tube is desirably, though not necessarily, of a material having a higher softening point than the material of the body. The tube may optionally include a narrowed or “drawn down” portion along the length or at an end thereof to provide extremely fine structure. By shaping depressions or holes to receive the tube in layers of refractory material that are fired or sintered to form the device, the tube can be assembled together with the layers and fired or sintered to form a consolidated refractory microfluidic device.

This application claims the benefit of priority under 35 U.S.C. §119(e) of U.S. Provisional Application Ser. No. 60/686,190 filed on May 31, 2005.

### BACKGROUND OF THE INVENTION

1. Field of the Invention

The present invention relates generally to microfluidic devices, and particularly to refractory-material microfluidic devices with embedded tubular structures.

2. Technical Background

Compared to conventional fluidic processing devices, internal dimensions of microfluidic processing devices, generally understood as being in the millimeter to micrometer range, provide high surface-to-volume ratios, resulting in high mass and heat transfer rates with low reaction volumes.

Refractory materials such as ceramics, glass, glass-ceramics and the like generally have in common resistance to high temperatures and resistance to chemical attack. These properties make refractory materials attractive for use in microfluidic devices for chemical processing. But forming microfluidic structures in such materials can be difficult. The otherwise desirable durability of such materials makes subtractive forming processes, such as physical or chemical etching, typically expensive and unfriendly to the environment.

Non-subtractive forming processes have been disclosed, such as molding layers of glass frit on substrates, followed by stacking and final sintering (see, e.g., U.S. Pat. No. 6,769,444, assigned to the present assignee). Forming structures in layers of green ceramic, followed by stacking and firing, has also been suggested. (See, e.g., U.S. Pat. No. 5,993,750.) Devices formed of fired or sintered refractory materials can achieve good performance in terms of durability and high temperature capability. But with devices comprised of refractory materials, it can be difficult to achieve extremely fine structures or fluid passages within the structure. With manufacturing processes requiring a final sintering or firing to consolidate the fluidic devices, extremely fine structures or fluid passages designed into the structure may not survive the final sintering or firing intact. Yet fine structures are desirable for various applications, including, for example, precise and rapid temperature sensing, pinpoint sensing of other types, pinpoint sampling or injection of fluid, precisely targeted heating or cooling, and the like.

### SUMMARY OF THE INVENTION

The present invention provides a microfluidic device comprising a body of refractory material having one or more fluid passages of millimeter-or sub-millimeter scale defined therein, and a tube of refractory material embedded in said body, the tube having a millimeter- or sub-millimeter-scale passage therein and first and second ends. This allows the reliable, repeatable formation of very precise, very fine tubular features within a refractory microfludic device. The tube is desirably, though not necessarily, of a material having a higher softening point than the material of the body. The tube may optionally include one or more narrowed or “drawn down” portions along the length or at an end thereof to provide extremely fine structure. By shaping depressions or holes to receive the tube in the layers of refractory material that are fired or sintered to form the device, the tube can be assembled together with the layers and fired to form a consolidated refractory microfluidic device.

The present invention is particularly useful for high performance temperature sensors within refractory material microfludic devices. Sensors can be located within the center of microfluidic channels to be sensed, surrounded by the fluid within the channel and separated from it by only a thin wall of the tube.

Additional features and advantages of various embodiments of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description present embodiments of the invention, and are intended to provide an overview or framework for understanding the nature and character of the invention as it is claimed. The accompanying drawings are included to provide a further understanding of the invention, and are incorporated into and constitute a part of this specification. The drawings illustrate various embodiments of the invention, and together with the description serve to explain the principles and operations of the invention.

### BRIEF DESCRIPTION OF THE DRAWINGS

FIG. 1 is an elevational view of a prior art layered microfluidic device.

FIG. 2 is a cross-sectional plan view of structure within the central layer in the prior device of FIG. 1.

FIG. 3 is a cross-sectional plan view of a microfluidic device according to one embodiment of the present invention, incorporating a fine tubular structure into a device of the type shown in FIG. 2.

FIG. 4 is a cross-sectional plan view of a microfluidic device according to another embodiment of the present invention.

FIG. 5 is a cross-sectional plan view of a microfluidic device according to yet another embodiment of the present invention.

FIG. 6 is a cross-sectional plan view of a microfluidic device according to still another embodiment of the present invention.

FIG. 7 is a cross-sectional view of one embodiment of tube of refractory material useful in one or more aspects of the present invention.

FIG. 8 is a cross-sectional view of another embodiment of a tube of refractory material useful in one or more aspects of the present invention.

FIG. 9 is a cross-sectional view of yet another embodiment of a tube of refractory material useful in one or more aspects of the present invention.

FIG. 10 is a cross-sectional plan view of a microfluidic device according to still another embodiment of the present invention.

FIG. 11 is an elevational cross sectional view of an embodiment of layers of refractory material useful in one or more aspects of the present invention an annular seal useful between microfluidic devices of the present invention.

FIG. 12 is a cross-sectional plan view of a microfluidic device according to yet another embodiment of the present invention.

FIG. 13 is an enlarged view corresponding to a portion of FIG. 12 and showing one aspect of yet another embodiment of the present invention.

FIG. 14 is a cross-sectional plan view of a microfluidic device according to still another embodiment of the present invention.

### DETAILED DESCRIPTION OF THE PREFERRED EMBODIMENTS

Reference will now be made in detail to embodiments of the invention, examples of which are illustrated in the accompanying drawings. Whenever possible, the same reference numerals will be used throughout the drawings to refer to the same or like parts.

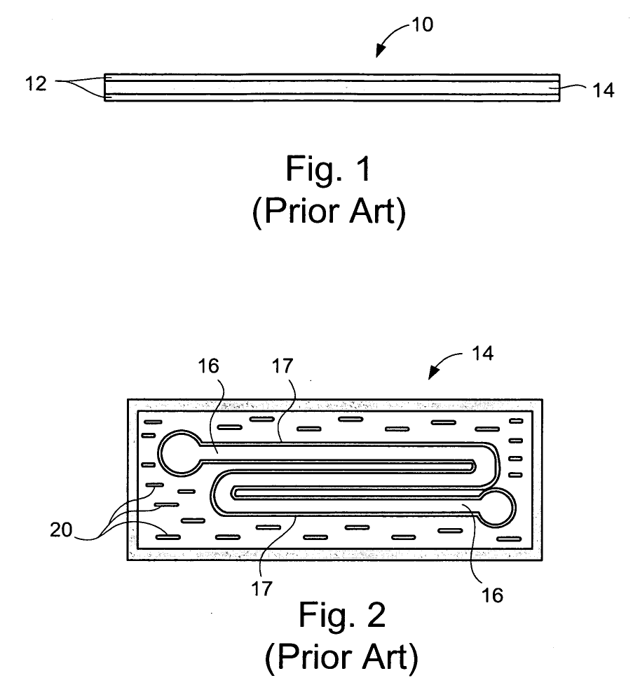

FIG. 1 is an elevational view of a prior art microfludic device 10 of the type disclosed in U.S. Pat. No. 6,769,444. Glass substrates 12 enclose a central layer 14 formed of molded then pre-sintered glass frit. The entire structure is consolidated together by stacking and final sintering.

A possible structure of the central layer 14 of the microfludic device 10 of FIG. 1 is shown in cross-sectional view through the layer 14 FIG. 2. The layer 14 of sintered frit forms a microfludic passage 16 defined by passage walls 17 within the microfluidic device 10. The layer 14 also forms an outer wall 18 and other supporting structures 20.

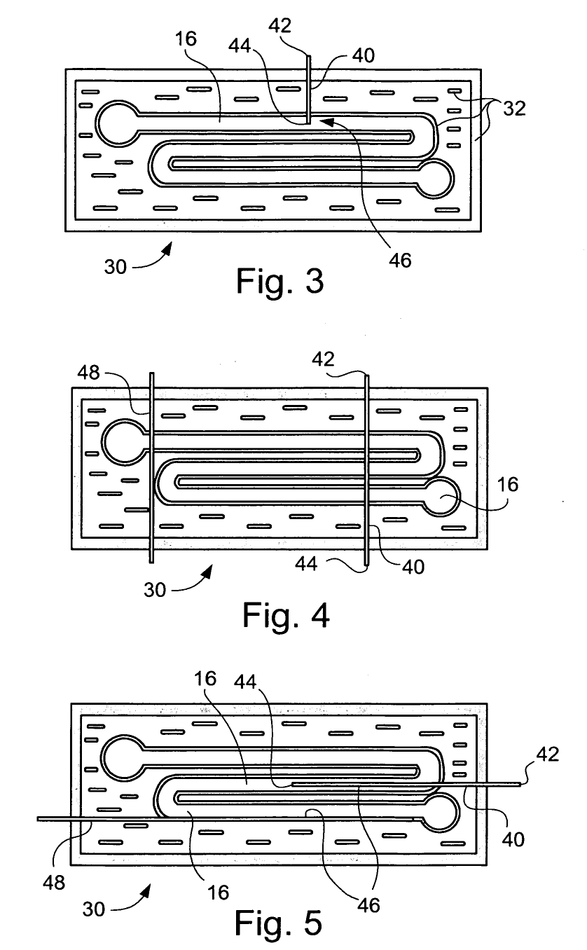

An embodiment of the refractory microfluidic device of the present invention is shown in FIG. 3, and the device is designated generally throughout by the reference numeral 30. Microfluidic device 30 is formed of refractory material 32, such as a molded then sintered glass frit which may be arranged between two or more substrates, as shown in FIG. 1 (Prior Art), or such as a green ceramic composition patterned on a surface thereof to form the structures shown, then sintered together with one or more additional layers of like material. Integrated or embedded within microfluidic device 30 is a tubular structure or tube 40. Tube 40 is also formed of a refractory material, such as glass, fused quartz, ceramic, or the like, and desirably though not necessarily has a higher softening temperature than that of the refractory material 32. The tube 40 is integrated or embedded into the device 30 by the sintering or firing of the device structure. Because the tube 40 may be of very small dimensions, such as a capillary tube or a drawn-down capillary tube, very small and fine features may be achieved in the device 30. Because the tube 40 desirably has a higher softening temperature or at least different firing properties giving it resistance to deformation, the fine features provided by the tube are preserved through final firing or sintering into the final device 30.

As shown in FIG. 3, one end 42 of the tube 40 may extend to or beyond the exterior of device 30 to provide access from the exterior to the interior of the device. The other end 44 of the tube 40 may extend to or into the microfluidic passage 16. In this embodiment the end 44 extends into the passage 16, resulting in a portion 46 of the tube 40 that lies within fluid passage 16. The end 44 of the tube 40 may be closed, allowing sensing of the contents of passage 16 through the tube wall and end. The end 44 of tube 40 may also be open, allowing sensing, sampling, small precise injections of reactants, and the like through the tube 40.

FIG. 4 shows another embodiment of a microfluidic device like that of FIG. 3. As shown in FIG. 4, the device 30 may include multiple tubes such as tubes 40 and 48, and the tubes may extend across the entire device 30, without ending at or within a fluid passage in the device. The tubes may extend through one fluid passage as with tube 48, or through multiple fluid passages (or multiple portions of the same passage 16) as with tube 40.

FIG. 5 shows yet another embodiment of a microfluidic device 30 of the present invention. In this embodiment, tubes 40 and 48 are integrated into the device 30 along the length of fluid passages within the device. This results in relatively lengthy portions 46 of the respective tubes 40 and 48 being positioned within the fluid passage(s) 16. Such positioning of tubes 40 and 48 allows for the potential of sensing at multiple locations along the passage(s) 16 with a single access tube. Such multiple sensing may be performed, for instance, simultaneously with multiple sensors, or serially by moving a single sensor along the tube. If a directional optical sensor is employed, it can be rotated within the tube as well as desired. If a perforated or otherwise permeable tube is employed, very fine multiple injections can be performed along the length of a passage. Note that tubular structure 48, as shown in FIG. 5 illustrating this embodiment of the present invention, is embedded in a wall of fluid passage 16, such that only a part of the circumference of the tubular structure 48 is included in the portion 46 of the tube that is positioned within the fluid passage 16.

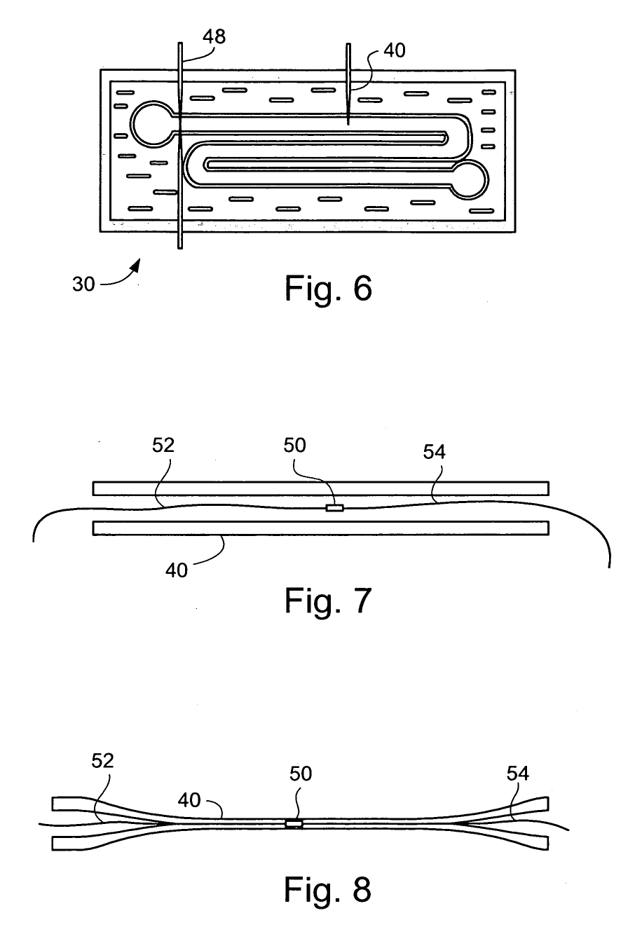

FIG. 6 shows another embodiment of the microfluidic device 30 of the general type shown in FIG. 3. As shown in FIG. 6, the one or more tubes 40 and 48 may be narrowed or “drawn down” to a smaller diameter if desired, particularly where they are to be in contact with fluid passage 16. Where the tubes are used for temperature probe access, the narrowed tubes and thinned tube walls in the drawn-down sections allow better thermal transmission across the tube. If a sensor is to be inserted into such a narrowed tubular structure, the narrowed portion (or the pointed end, if the narrowed portion is at an end) can also be useful to “funnel in” and precisely locate an inserted sensor.

FIG. 7 shows an embodiment of a tube 40 useful in devices such as those shown in FIGS. 3-5. A sensor 50, such as a temperature sensor, is positioned within the tube 40. Sensor leads 52 and 54 may be used to position the sensor after tube 40 is integrated or embedded into a microfluidic device. Alternatively, in cases where the sensor 50 and leads 52, 54 can withstand high temperatures, tube 40 may be drawn down over the sensor 50, as shown in FIG. 8, prior to being embedded in a microfluidic device. This allows very close possible contact between the sensor and the walls of the tube 40, and close thermal and/or optical coupling of the sensor to the environment surrounding the tube 40. Similar embodiments may be constructed with single-lead sensors also, or where both leads are fed off to one side together, and where the tube is narrowed at and end thereof.

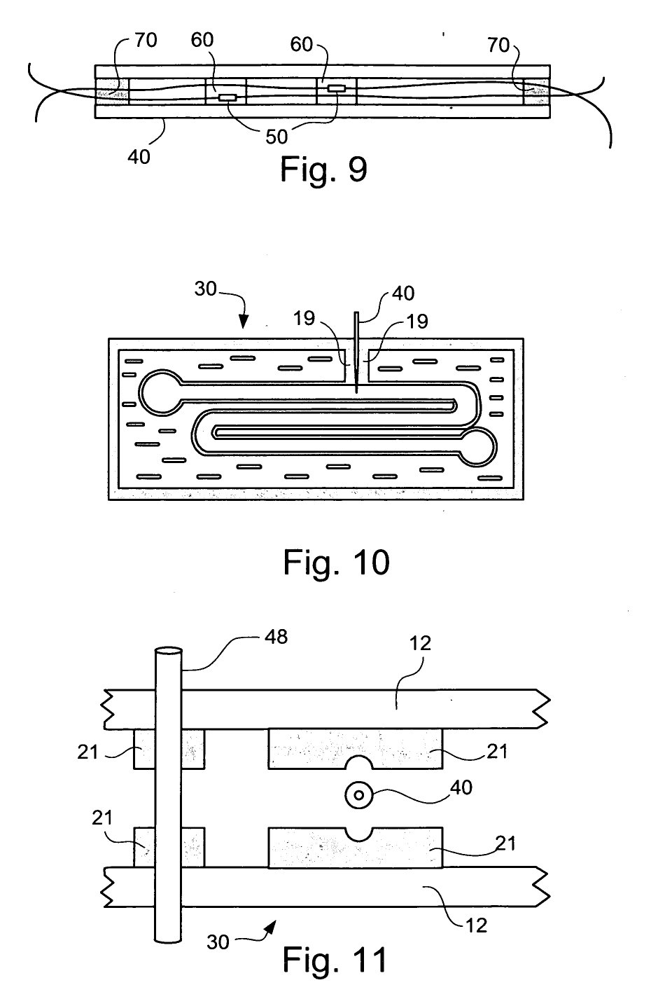

FIG. 9 shows another embodiment of a tube 40 useful in devices such as those shown in FIGS. 3-5. Multiple sensors 50 may be positioned within a single tube 40, so as to align with desired sensing locations such as the multiple fluid passages along tube 40 of FIG. 4. A coupling medium 60, such as a thermal or optical coupling medium, may be introduced into the tube 40 with the sensors 50 to improve coupling of the sensors to the tube. The ends of the tube 40 may be sealed with a sealant 70.

In the embodiment of FIG. 10, the microfluidic device 30 includes additional refractory material 19 along the path of tubular structure or tube 40. Additional material 19 may be needed in some circumstances to ensure sealing of the refractory material of the bulk device 30 to the refractory material of the tube 40. To further ensure such sealing, it is desirable that depressions or cavities or holes or the like be formed in the refractory material of the bulk device 30, prior to final firing or sintering, to receive and hold the tube 40 or the one or more tube 40 and 48.

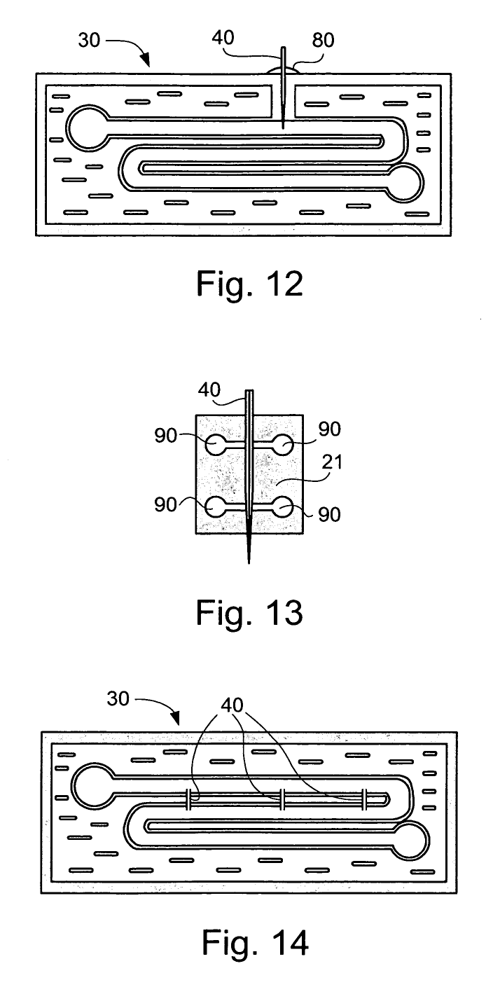

FIG. 11 shows a cross section of a device 30 prior to final assembly and firing. Shaped pre-final-firing structures 21 of refractory material are supported on substrates 12. Holes are provided through substrates 12 and structures 21 for placement of tube 48, while depressions or cavities that conform to tube 40. The depressions or cavities may only generally conform to the shape of the tube 40, and may be of smaller radius than the tube for instance, or may have otherwise have a slight excess of pre-final-firing material than that which would conform in pre-firing state to the shape of the tube 40. The two substrates are then brought together around the tube 40 and final firing or sintering is performed. One alternative sealing technique is adding a sealant 80 on the exterior of the device 30 around the tube 40 before or after final firing or sintering, as illustrated in FIG. 12. Another sealing technique that may be employed is forming passages and reservoirs 90 for sealing frit or other sealing material. The sealing material in such passages and reservoirs 90 may be placed in the reservoirs prior to filing to be activated by the firing process and fill any gaps between additional refractory material 21 and tube 40. Alternatively, the passages and reservoirs 90 may be designed to remain empty and accessible from the exterior of the device after firing, when a sealant material may be injected from the exterior of the device to produce the desired sealing.

The present invention also finds use in the design and architecture of the internal fluid passages within the device 30, as illustrated in FIG. 14. The embedded tubes or tubular structures 40 used in the present invention need not extend to the exterior of the device 30, and may be used for varying the available fluidic passage designs.

It will be apparent to those skilled in the art that various modifications and variations can be made to the present invention without departing from the spirit and scope of the invention. Thus it is intended that the present invention cover the modifications and variations of this invention provided they come within the scope of the appended claims and their equivalents.

What is claimed is:

1. A microfluidic device comprising:
a body of refractory material having one or more fluid passages of millimeter- or sub-millimeter scale defined therein; and
a tube of refractory material embedded in said body, the tube having a millimeter- or sub-millemeter-scale passage therein and first and second ends, the tube being positioned such that at least a first portion of said tube lies within at least one of said one or more fluid passages.

2. The device of claim 1 wherein the tube, at the first portion of the tube, is fully surrounded by said one of said one or more fluid passages.

3. The device of claim 1 wherein the tube, at the first portion of the tube, is only partially surrounded by said one of said one or more fluid passages.

4. The device of any of claim 1 wherein the first portion of the tube is narrowed relative to a second portion of the tube.

5. The device of any of claim 2 wherein the first portion of the tube is narrowed relative to a second portion of the tube.

6. The device claim 1 wherein the first portion of the tube includes the second end of the tube.

7. The device claim 2 wherein the first portion of the tube includes the second end of the tube.

8. The device claim 5 wherein the first portion of the tube includes the second end of the tube.

9. The device of claim 1 wherein the first portion of the tube includes neither end of the tube.

10. The device of claim 4 wherein the first portion of the tube includes neither end of the tube.

11. The device of claim 1 wherein at least the first end of the tube is open to the outside of said body.

12. The device of claim 11 wherein both the first and the second ends of the tube are open to the outside of said body.

13. The device of any of claim 1 wherein the tube comprises a glass tube having a higher softening point than the material of said body.

14. The device of any of claim 13 wherein the body comprises a glass frit.

15. A microfluidic device comprising:
a body of refractory material having one or more fluid passages of millimeter-or sub-millimeter scale defined therein; and
a tube of refractory material embedded in said body, the tube having a millimeter- or sub-millemeter-scale passage therein and first and second ends, the tube being positioned such that said tube is in fluid communication with at least one of said one or more fluid passages at at least one of said first and second ends.

16. A method of making a microfluidic device, the method comprising:
forming a refractory material, in a pre-fired or pre-final-sintered state, into structured layers for stacking to form a body containing fluid passages, said structured layers including one or more depressions or holes shaped for receiving one or more tubes;
stacking or assembling said structured layers together with one or more tubes, said one or more tubes comprised of a post-firing or post-final sintering refractory material, said tubes being placed in said one or more depressions or holes;
firing or sintering the stacked structured layers and tubes together to form a body of refractory material having one or more fluid passages defined therein and having one or more tubes of refractory material embedded in said body.

17. The method of claim 16 wherein the refractory material of said tubes has a higher softening temperature than the refractory material of said structured layers.
